(19) United States
(12) Patent Application Publication
(10) Pub. No.: US 2026/0340227 A1
(43) Pub. Date: Oct. 29, 2026

(54) GOLDEN-LADDER MASS-INDEX GENERATOR METHODS AND SYSTEMS FOR PARAMETER-FREE FERMION MASS TABLES VIA INTEGER PHI-LADDER INDICES DERIVED FROM QUANTUM NUMBERS

(71) Applicant: Jonathan Washburn, Austin, TX (US)

(72) Inventor: Jonathan Washburn, Austin, TX (US)

(21) Appl. No.: 19/650,837

(22) Filed: Apr. 17, 2026

Related U.S. Application Data
(60) Provisional application No. 63/794,578, filed on Apr. 25, 2025.

(51) Int. Cl. G06F 30/25

(52) U.S. Cl. CPC G06F 30/25

(57) ABSTRACT

A computer-implemented mass-generation architecture receives a fermion identifier, determines a sector S and a generation g associated with a fermion, assigns a generation torsion value tau(g), assigns a species rung r_f from the sector S and the generation torsion value tau(g), determines a sector yardstick m_yard(S) from fixed sector constants associated with the sector S, and computes a fermion mass m_f according to m_f=m_yard(S)*phi\hat{ }(r_f), where phi is the golden ratio. The disclosed architecture thereby implements a fixed identifier-to-index-to-mass rule for generating fermion masses without per-species fitted mass parameters. In preferred embodiments, tau(0)=0, tau(1)=11, and tau(2)=17, and the species rung is assigned according to r_f=r_base(S)+tau(g). The architecture may generate a mass-only output, a structured single-species record, a mass table, or a ratio output.

### CROSS-REFERENCE TO RELATED APPLICATIONS

This application claims the benefit of U.S. Provisional Patent Application No. 63/794,578, filed on Apr. 25, 2025, the entire disclosure of which is incorporated herein by reference to the extent permitted.

### BACKGROUND OF THE INVENTION

The present disclosure relates generally to computer-implemented particle-mass generation and, more particularly, to methods and systems for generating fermion mass values and mass tables from particle-identifying information. More specifically, the present disclosure relates to computational architectures that receive a fermion identifier, determine a sector and generation associated with the fermion, assign a fixed integer ladder index derived from those quantum-number classifications, and compute a corresponding mass from a fixed sector yardstick and a phi-based ladder law without per-species fitted mass parameters.

In preferred implementations, the disclosed methods and systems are useful in particle-physics computation, mass-table generation, simulation initialization, lattice quantum chromodynamics parameterization, collider-event generation, and astroparticle Monte Carlo workflows. However, such implementations are application environments for use of the disclosed mass-generation architecture and do not define the invention itself. The invention is the deterministic identifier-to-index-to-mass architecture by which fermion mass values are generated from fixed sector structure, fixed integer ladder assignments, and fixed phi-based mass evaluation, without per-species fitted mass parameters.

In conventional Standard Model practice, fermion masses are typically treated as measured inputs rather than as outputs generated from a fixed computational rule. Quarks, charged leptons, and, in many contexts, neutrinos are handled as species-specific mass entries supplied to simulation, modeling, or calculation pipelines as parameters. As a result, mass handling can become fragmented across software environments, scale conventions, and calibration procedures when species masses are entered, tuned, or transported individually rather than generated from a common rule.

This issue is particularly significant in computational environments that benefit from deterministic and internally consistent mass assignment. For example, in lattice quantum chromodynamics workflows, quark masses may be used in connection with hopping-parameter initialization and related tuning procedures. Conventional workflows can require iterative kappa tuning for multiple quark flavors and lattice spacings, and may involve repeated manual adjustment or reconciliation of input masses across different computational settings. Manual mass entry and repeated tuning can increase setup burden, reduce reproducibility, and introduce inconsistencies across implementations.

Accordingly, a need exists for methods and systems that can receive a fermion identifier, determine the corresponding classification data, assign a fixed integer ladder position, compute the corresponding mass from fixed sector structure and a phi-based law, and output the resulting mass without per-species fitted mass parameters. A further need exists for such methods and systems to support single-species mass generation, mass-table generation, structured output records, and consistent downstream computational use, while preserving a clear distinction between the core mass-generation mechanism and optional downstream applications.

In conventional practice, no generally adopted computational architecture provides a parameter-free fermion mass table by taking known particle-classification inputs and converting those inputs through a fixed integer ladder rule into corresponding mass outputs. Instead, fermion masses are commonly handled as externally supplied quantities. This approach leaves unresolved the problem of generating a consistent mass output directly from particle identity information, including sector and generation information, using a deterministic and internally structured computation.

A further limitation of conventional approaches is that they do not provide a unified identifier-to-mass mechanism in which intra-sector mass relationships are preserved as exact structural relations of the generating rule itself. Where masses are entered independently, ratios among related particles are consequences of selected inputs rather than outputs of a common fixed architecture. In contrast, the presently disclosed architecture uses fixed generation torsion values, fixed sector baseline structure, fixed sector constants, and a phi-based yardstick law to generate mass values from a common rule. This permits the resulting mass values, and in preferred embodiments exact intra-sector ratio relations, to be produced from the same deterministic framework.

Conventional software environments may also require species-specific handling, separate lookup tables, repeated reconciliation among simulation codes, or repeated retuning when moving between applications or computational settings. These conditions can make it more difficult to maintain a single internally consistent source of fermion mass values across different workflows. The present disclosure addresses this deficiency by providing a mass-generation architecture in which a fermion identifier is resolved, a fixed integer rung is assigned, a fixed sector yardstick is determined, and a mass output is computed from that fixed structure.

### SUMMARY OF THE INVENTION

The present disclosure provides a computer-implemented method, system, and associated output architecture for parameter-free fermion mass generation. In a core implementation, a fermion identifier is received, a sector S and generation g associated with the fermion are determined, a fixed integer rung is assigned from those identifiers, a fixed sector yardstick is determined, and a mass is computed as a phi-power-based function of the yardstick and rung. The resulting mass is then output as a mass value, a structured record, or a mass-table entry, without the use of per-species fitted mass parameters. The disclosed architecture is deterministic once the relevant identifier information has been resolved.

In a canonical embodiment, the disclosed architecture uses the following mass forms:

m_f=(2\hat{ }(B_pow(S))*phi\hat{ }(−5)*phi\hat{ }(r0(S))*phi\hat{ }(r_f))/10\hat{ }6

m_f=m_yard(S)*phi\hat{ }(r_f)

m_yard(S)=(2\hat{ }(B_pow(S))*phi\hat{ }(−5)*phi\hat{ }(r0(S)))/10\hat{ }6
where m_f is the generated mass for fermion f, S is the sector associated with the fermion, B_pow(S) and r0(S) are fixed sector constants, phi is the golden ratio, m_yard(S) is a fixed sector yardstick, and r_f is a species rung assigned from fixed identifier-derived structure. In a canonical index-assignment embodiment, the disclosed architecture uses fixed generation torsion values tau(0)=0, tau(1)=11, and tau(2)=17, and assigns the species rung according to r_f=r_base(S)+tau(g), where r_base(S) is a fixed sector baseline rung.

In preferred embodiments, the disclosed architecture generates masses for charged leptons and quarks using canonical sector constants, canonical sector baseline structure, and canonical rung assignments derived from the corresponding generation torsion values. This charged-fermion embodiment provides a concrete implementation of the disclosed identifier-to-index-to-mass rule and may be used to generate single-species outputs, structured output records, sector-subset outputs, or a charged-fermion mass table. In preferred embodiments, the output may include, in addition to mass, associated sector, generation, and rung information for the requested fermion or fermions.

In a further preferred representation, the disclosed architecture may additionally provide a half-step ladder form defined by n_L=2*(r_f−r_base(S)), such that m_f=m_base(S)*phi\hat{ }(n_L/2) and m_(n_L+2)/m_(n_L)=phi. In preferred embodiments, the system may further provide exact intra-sector ratio outputs satisfying m_f/m_g=phi\hat{ }(r_f−r_g) for fermions within a common sector. The half-step and ratio forms are preferred representations and outputs of the disclosed architecture, but are not required to practice the core invention.

In system form, the disclosure provides an identifier intake and resolution module, a torsion and rung assignment module, a sector-yardstick module, a mass-evaluation module, and an output formatter. In certain embodiments, the architecture may further include optional packaging layers such as application programming interfaces, language bindings, serialized table exports, storage layers, plugin layers, or machine-readable table outputs. Such packaging layers are optional embodiments built on top of the disclosed identifier-to-index-to-mass architecture and do not define the core invention itself.

In another aspect, the disclosure supports output products including mass-only outputs, structured single-species records, multi-species tables, ratio outputs, precomputed machine-readable mass tables, and non-transitory computer-readable media storing instructions that perform the disclosed method. In certain embodiments, precomputed charged-fermion tables or sector-subset tables may be generated and stored for later retrieval while remaining derived from the same fixed identifier-to-index-to-mass rule.

In a further aspect, the disclosed implementation includes machine-checked support for fixed tau values, fixed rung assignments, fixed sector constants, positivity, monotonicity, and exact phi-ratio behavior. These machine-checked results support fixed and exact aspects of the disclosed architecture. By contrast, runtime metrics, latency, query rates, PDG comparisons, and downstream simulation performance are treated as benchmarks, empirical comparisons, or demonstrated examples rather than as mandatory features of the core invention.

In downstream embodiments, the generated masses may be used in lattice-QCD initialization, collider-event generation, cosmic-ray simulation, cross-code standardization, and related computational workflows. In particular embodiments, generated quark masses may be converted into lattice units and used to initialize kappa values for lattice-QCD workflows. These downstream uses are exemplary application environments for the generated outputs and are not required to practice the claimed identifier-to-index-to-mass generator; the inventive core is the deterministic computation that maps an identifier (or a resolved sector S and generation g) to a rung r_f and to a mass m_f using fixed torsion values and fixed sector structure, without per-species fitted mass parameters.

In prophetic or extension embodiments, the disclosed indexing framework may be extended to higher-rung hypothetical fermions, boson mass tables, neutrino index modules with separate absolute-scaling logic, running-mass transport formulations, and other future particle-physics applications. Such extension embodiments remain subordinate to the fixed identifier-to-index-to-mass architecture disclosed herein.

### BRIEF DESCRIPTION OF THE DRAWINGS

FIG. 1 is a block diagram of an overall mass-generation system architecture. FIG. 1 shows an input fermion identifier 100, a parser or normalizer 102, a sector and generation resolver 104, a generation torsion module 106, a sector baseline module 108, a rung assignment module 110, a sector yardstick module 112, a mass-evaluation module 114, an output formatter 116, a single-mass output 118, a mass-table output 120, and an optional packaging layer 122.

FIG. 2 is a flow diagram of identifier normalization and index assignment. FIG. 2 shows a received identifier 200, a canonicalization step 202, an alias resolution table 204, a sector determination step 206, a generation determination step 208, a validity check 210, a generation torsion lookup 212, a sector baseline lookup 214, a rung computation step 216, an optional half-step computation step 218, an unsupported or ambiguous input return 220, and a canonical species record output 222.

FIG. 3 is a canonical table figure showing fixed sector constants, baseline rungs, generation torsion values, and resulting charged-fermion rung assignments. FIG. 3 shows a lepton sector block 300, an up-quark sector block 302, a down-quark sector block 304, an electroweak reference block 306, fixed generation torsion values 308, lepton baseline rung values 310, up-quark baseline rung values 312, down-quark baseline rung values 314, a charged-fermion canonical table 316, and optional half-step baseline markers 318.

FIG. 4 is a mathematical-processing figure showing mass-evaluation forms, preferred half-step representation, exact intra-sector phi-ratio identities, and fallback output modes. FIG. 4 shows a full mass-law equation block 400, a yardstick equation block 402, a compact mass-evaluation block 404, a logarithmic evaluation block 406, a half-step equation block 408, an exact ratio identity block 410, a mass-only output block 412, a structured-record output block 414, and a precomputed-table output block 416.

FIG. 5 is a downstream-use figure showing lattice-QCD initialization from generated mass values. FIG. 5 shows a lattice spacing input 500, a generated quark-mass table 502, a lattice-unit conversion block 504, a kappa computation block 506, an HMC initialization block 508, a conventional iterative tuning path 510, a disclosed direct-initialization path 512, and an optional benchmark or validation block 514. FIG. 5 illustrates one downstream use of mass values generated by the disclosed identifier-to-index-to-mass architecture and does not redefine the core invention.

FIG. 6 is an output-products and storage figure showing output embodiments generated from the core mass-generation architecture. FIG. 6 shows a mass-only output 600, a structured single-species record 602, a sector-subset table 604, a charged-fermion full table 606, a ratio output 608, a precomputed machine-readable table 610, a non-transitory storage medium 612, and a retrieval or output interface 614.

FIG. 7 is a support-and-validation figure showing formal support for fixed mathematical properties of the disclosed mass-generator architecture and separate empirical benchmark branches. FIG. 7 shows the disclosed mass-generator architecture 700, fixed tau-value support 702, fixed rung-value support 704, fixed sector-constant support 706, positivity support 708, monotonicity support 710, exact phi-ratio support 712, an empirical benchmark branch 714, a runtime or query benchmark 716, a PDG comparison benchmark 718, a lattice benchmark 720, and a cosmic-ray benchmark 722.

### DETAILED DESCRIPTION OF THE INVENTION

The present disclosure provides a computer-implemented mass-generation architecture that converts fermion-identifying information into mass outputs through a fixed identifier-to-index-to-mass rule. In the disclosed architecture, a fermion identifier is received, a sector S and generation g associated with the fermion are determined, a fixed integer rung r_f is assigned from those identifiers according to fixed generation torsion and fixed sector baseline structure, a fixed sector yardstick is determined from fixed sector constants, and a corresponding fermion mass is computed from a phi-based ladder law. The resulting mass may be output as a single mass value, a structured record, or a mass-table entry without per-species fitted mass parameters. Once the relevant identifier information has been resolved into sector and generation, the disclosed index assignment and mass evaluation are deterministic.

In a canonical implementation, the mass-generation rule is expressed as:

m_f=(2\hat{ }(B_pow(S))*phi\hat{ }(−5)*phi\hat{ }(r0(S))*phi\hat{ }(r_f))/10\hat{ }6 or equivalently as:

m_f=m_yard(S)*phi\hat{ }(r_f)
where:

m_yard(S)=(2\hat{ }(B_pow(S))*phi\hat{ }(−5)*phi\hat{ }(r0(s)))/10\hat{ }6

In a canonical index-assignment implementation, generation torsion is fixed according to:
tau(0)=0
tau(1)=11
tau(2)=17
and the species rung is assigned according to:

r_f=r_base(S)+tau(g)
where r_base(S) denotes a fixed sector baseline rung and g denotes the generation associated with the fermion.

As described in greater detail below, the disclosed architecture may be implemented in single-species, structured-record, sector-subset, and mass-table embodiments. Preferred embodiments further provide half-step representations, exact intra-sector phi-ratio outputs, charged-fermion table generation, and downstream computational use.

As used herein, a “fermion identifier” refers to any machine-readable, user-supplied, or system-supplied input that identifies, directly or indirectly, a fermion for which a mass is to be generated. A fermion identifier may include, by way of example, a particle name, symbol, canonical species token, sector-and-generation pair, or other structured input sufficient to resolve the fermion to a supported category within the disclosed architecture.

As used herein, a “sector” or “sector S” refers to a category used by the disclosed mass-generation architecture to select fixed sector structure for mass computation. In canonical embodiments described herein, sectors include at least a lepton sector, an up-quark sector, and a down-quark sector. In certain embodiments, an electroweak reference sector or other extension sector may also be defined for reference, comparison, or extension purposes.

As used herein, a “generation” or “generation g” refers to the family index associated with a fermion within a supported sector. In canonical embodiments, the generation index is one of g=0, g=1, or g=2. The generation index is used to determine a fixed generation torsion value and thereby contributes to assignment of a corresponding species rung.

As used herein, “generation torsion” or “tau(g)” refers to a fixed integer value associated with the generation index. In the canonical implementation disclosed herein, generation torsion is fixed according to:
tau(0)=0
tau(1)=11
tau(2)=17

These values are used in the disclosed identifier-to-index-to-mass rule and are not treated as per-species fit parameters.

As used herein, a “sector baseline rung” or “r_base(S)” refers to a fixed baseline integer associated with a sector and used in determining a species rung for a fermion in that sector. As used herein, a “species rung” or “r_f” refers to the integer ladder position assigned to a fermion after sector and generation have been resolved. In canonical embodiments, the species rung is assigned according to:

R_f=R_base(s)+Tau(g)
such that the rung assignment is deterministic once sector S and generation g are known.

As used herein, a “sector yardstick” or “m_yard(S)” refers to a fixed mass-scale quantity associated with a sector and determined from fixed sector constants. In canonical embodiments described herein:

m_yard(S)=(2\hat{ }(B_pow(S))*phi\hat{ }(−5)*phi\hat{ }(r0(S)))/10\hat{ }6
where B_pow(S) and r0(S) are fixed sector constants for sector S, and phi is the golden ratio. The sector yardstick is combined with the species rung to compute the generated fermion mass.

As used herein, “phi” refers to the golden ratio. In the disclosed architecture, phi is used in the mass law, in preferred ratio identities, and in preferred half-step formulations. As used herein, a “phi-ladder” refers to the integer-indexed mass structure in which a fermion mass is generated as a phi-power-based function of a sector yardstick and an assigned rung.

As used herein, a “half-step index” or “n_L” refers to a preferred baseline-relative representation of ladder position. In preferred embodiments: n_L=2*(r_f−r_base(S)), where r_base(S) is the sector baseline rung for sector S. In the corresponding preferred half-step mass form, m_f=m_base(S)*phi\hat{ }(n_L/2). In preferred embodiments, the half-step representation supports the identity m(n_L+2)/m(n_L)=phi. The half-step index is a preferred representation and output form, but is not required for practice of the core identifier-to-index-to-mass architecture.

As used herein, a “mass-only output” refers to an output containing a generated mass value without requiring additional metadata. As used herein, a “structured output record” refers to an output containing a generated mass value together with one or more associated data fields, which may include sector, generation, torsion value, rung, half-step index, canonical species label, or related information. As used herein, a “mass table” refers to a data structure containing generated mass outputs for multiple supported fermions. A mass table may include, for example, a charged-fermion full table, a sector-subset table, or a precomputed machine-readable table derived from the disclosed architecture.

As used herein, a “ratio output” refers to an output that provides a relationship between masses of two fermions, preferably two fermions within a common sector. In preferred embodiments, ratio outputs may satisfy exact intra-sector phi-ratio identities of the form:

m_f/m_g=phi\hat{ }(r_f−r_g)
for fermions f and g within a common sector.

As used herein, a “precomputed machine-readable mass table” refers to a stored table, record set, memory image, or other data structure containing one or more mass outputs generated according to the disclosed fixed identifier-to-index-to-mass rule. Such a table may be stored in memory, on a non-transitory computer-readable medium, or in another storage embodiment, while remaining derived from the same disclosed architecture.

As used herein, a “benchmark” refers to an empirical performance, comparison, or implementation result, such as runtime, query rate, latency, PDG comparison, lattice-QCD performance, or simulation comparison. A benchmark is not, by itself, a required feature of the core invention unless expressly recited as such. As used herein, a “demonstrated example” refers to an implemented or described example supported as having been carried out or benchmarked in the disclosed materials. As used herein, a “prophetic example” refers to a future-facing, predictive, hypothetical, or not-yet-validated example or embodiment.

As used herein, a “mathematical identity” refers to a relation presented as exact within the disclosed architecture, such as a fixed torsion assignment, a fixed rung assignment rule, a canonical mass form, positivity, monotonicity, or an intra-sector phi-ratio identity. As used herein, “formal-verification support” refers to machine-checked support for disclosed mathematical properties of the architecture, including in preferred embodiments fixed tau values, fixed rung values, fixed sector constants, positivity, monotonicity, and phi-ratio behavior. Formal-verification support is technical support for fixed and exact aspects of the disclosed architecture and is distinct from empirical benchmarks or future predictions.

As used herein, “core invention” refers to the fixed identifier-to-index-to-mass computational architecture by which a fermion identifier is converted into a sector and generation, then into a species rung, then into a sector-yardstick-based mass, without per-species fitted mass parameters. As used herein, “preferred embodiment” refers to an embodiment that uses the core architecture together with disclosed preferred forms such as half-step indexing, charged-fermion tables, structured outputs, or specific computation forms. As used herein, “downstream embodiment” refers to an application of the generated mass outputs in another workflow, including by way of example lattice-QCD initialization or simulation use. As used herein, “extension embodiment” refers to a disclosed additional embodiment, such as boson tables, neutrino modules, higher-rung hypothetical particles, or running-mass transport, that remains subordinate to the core disclosed architecture.

The disclosed mass-generation architecture operates on input information sufficient to identify, directly or indirectly, a fermion for which a mass is to be generated. In preferred embodiments, the input is provided as a fermion identifier that can be resolved into a sector S and a generation g. The architecture is not limited to a single input format, provided that the supplied input permits deterministic resolution to the classification data used by the disclosed identifier-to-index-to-mass rule.

In various embodiments, the input may comprise a particle name, a particle symbol, a canonical species token, a structured record containing sector and generation information, or a direct sector-and-generation input. By way of example, an input may identify a charged lepton, an up-type quark, or a down-type quark by name or symbol. In other embodiments, the input may bypass name parsing entirely and directly provide sector S and generation g as machine-readable fields. These different input forms are alternative input embodiments for the same core architecture and do not alter the disclosed mass law, torsion assignment, rung assignment, or yardstick computation.

In a preferred implementation, an input identifier is first normalized into a canonical internal form before index assignment is performed. For example, multiple aliases, labels, abbreviations, or symbol forms that refer to the same fermion may be resolved to a single canonical species representation. This normalization step improves consistency of downstream processing, but is not itself the inventive core. The inventive core begins once the relevant fermion has been deterministically resolved into the classification information used by the disclosed identifier-to-index-to-mass rule.

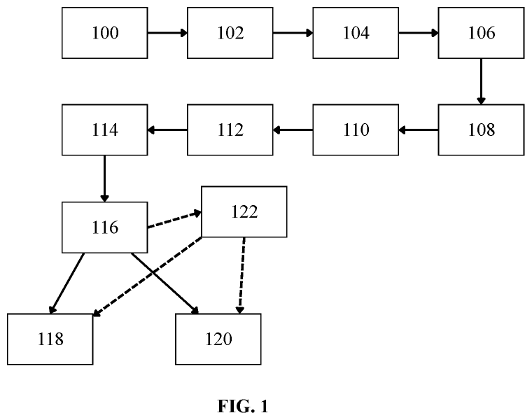

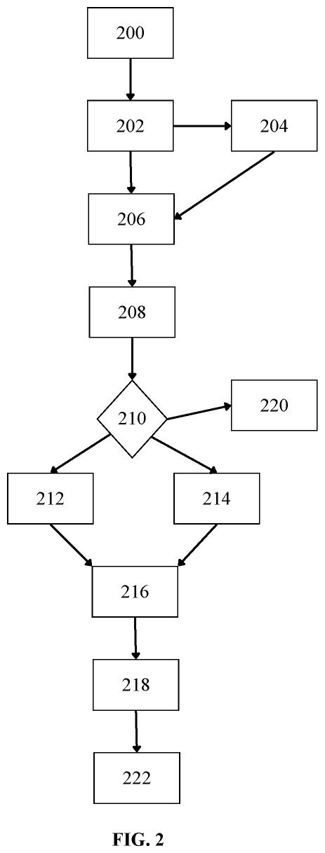

As shown in FIG. 1, an input fermion identifier 100 may be supplied to parser or normalizer 102, and as shown in FIG. 2, a received identifier 200 may be subjected to canonicalization step 202 and, where appropriate, alias resolution table 204. After normalization, the input is resolved into sector and generation information for subsequent use in torsion assignment, rung assignment, yardstick determination, and mass evaluation. The figures illustrate one preferred processing arrangement; equivalent intake and normalization arrangements may be used so long as the input is resolved into supported classification data for the disclosed mass-generation architecture.

In preferred embodiments, the disclosed architecture accepts at least the following classes of input:
a. a single-species identifier for generation of a single mass output;
b. a plurality of species identifiers for generation of a multi-species table;
c. a sector-restricted identifier set for generation of a sector-subset table;
d. a direct sector-and-generation input for bypassing name or symbol parsing; and
e. a structured request specifying a desired output form, including by way of example mass-only output, structured-record output, ratio output, or table output.

In embodiments using a single-species identifier, the system may output only a mass value or may output a structured record containing associated metadata such as sector, generation, rung, and optional half-step index. In embodiments using multiple identifiers, the system may generate a charged-fermion full table, a sector-subset table, or another multi-species table derived from the same fixed architecture. In embodiments using direct sector-and-generation input, the system may omit species-name normalization and proceed directly to assignment of generation torsion, species rung, and sector yardstick.

In preferred implementations, the input stage includes a validity check to determine whether the supplied identifier resolves unambiguously to a supported fermion category. If multiple aliases map to the same canonical species, the system may normalize all such aliases to one canonical species record. If an identifier does not resolve uniquely, or does not correspond to a supported category in the currently invoked embodiment, the system may return an ambiguity output, an unsupported-input output, or another error condition rather than assigning a mass on an indeterminate basis. This preserves the deterministic character of the disclosed architecture.

As shown in FIG. 2, validity check 210 may be used to determine whether a received identifier can be processed further by evaluating whether the received identifier resolves to exactly one supported canonical species record 222 (or to exactly one supported (sector S, generation g) pair). If valid, the identifier is passed to generation torsion lookup 212 and sector baseline lookup 214 after sector determination 206 and generation determination 208. If invalid or ambiguous, the input is directed to unsupported or ambiguous input return 220 rather than generating a mass on an indeterminate basis. In certain embodiments, the unsupported or ambiguous input return 220 includes a machine-readable status output specifying at least one of: (i) unsupported identifier, (ii) ambiguous identifier, (iii) unsupported sector, (iv) unsupported generation, or (v) invalid request format.

In some embodiments, the disclosed architecture may additionally accept extension-category inputs that are not processed through the canonical charged-fermion path. For example, a neutrino-related input, a boson-related input, or a hypothetical higher-rung input may be routed to a separate extension path when such an extension path is enabled. However, in the absence of such an enabled extension embodiment, the preferred input-processing path is the charged-fermion core path supported by the canonical sector and generation framework disclosed herein. Extension routing, where present, remains subordinate to the core identifier-to-index-to-mass architecture.

Thus, the input stage of the disclosed architecture provides a deterministic gateway into the fixed computational mass-generation rule. Regardless of whether the supplied input is a name, symbol, canonical token, structured record, or direct sector-and-generation pair, the purpose of the input stage is to provide resolved sector and generation information suitable for the fixed generation torsion, rung assignment, yardstick determination, and mass-evaluation operations described below.

In preferred embodiments, a received fermion identifier is normalized into a canonical internal representation before fixed index assignment and mass evaluation are performed. Identifier normalization and parsing are preparatory operations that permit the disclosed mass-generation architecture to accept different forms of input while preserving a deterministic downstream computation. These preparatory operations do not alter the fixed torsion values, fixed sector baseline structure, fixed sector constants, or fixed mass law used by the core architecture.

As shown in FIG. 1, input fermion identifier 100 may be received by parser or normalizer 102. As shown in FIG. 2, a received identifier 200 may be subjected to canonicalization step 202 and, where applicable, alias resolution table 204. In a preferred embodiment, the purpose of these operations is to convert the supplied identifier into a canonical species representation or into direct sector-and-generation information suitable for subsequent deterministic processing.

In various embodiments, the received identifier may include a textual particle name, a symbol, a canonical token, a structured request object, or other machine-readable input. Parsing may include token recognition, symbol recognition, delimiter handling, whitespace normalization, case normalization, or other conventional preprocessing operations sufficient to reduce multiple input variants to a canonical internal form. For example, different labels that refer to the same supported fermion may be mapped to one canonical species record. In such embodiments, the normalization logic serves only to identify the fermion unambiguously and does not itself define the mass-generation rule.

In a preferred parsing path, the received identifier is first canonicalized at step 202. Canonicalization may include transforming the input into a standard internal token or species key. The resulting canonical token may then be checked against alias resolution table 204 or an equivalent mapping structure that associates one or more permitted input forms with a single canonical species representation. Once a canonical representation is obtained, the system proceeds to determine sector and generation information used by the fixed mass-generation architecture.

In some embodiments, alias resolution table 204 may include entries that map multiple equivalent labels to the same fermion. By way of example, distinct textual representations, abbreviations, or symbol forms may resolve to a common canonical species record. Where multiple aliases map to the same species, the system preferably normalizes all such aliases to that single canonical record before continuing. This avoids duplicate species definitions and preserves deterministic downstream processing.

In other embodiments, parsing may be bypassed in whole or in part. For example, when the input already contains explicit sector S and generation g, the system may omit name-based canonicalization and proceed directly to sector determination step 206 and generation determination step 208, or directly to later stages if those data are already validated. Likewise, in machine-to-machine embodiments, the input may be supplied as a structured object whose fields already specify the classification data needed for the fixed torsion and rung assignments. Such bypass embodiments remain implementations of the same disclosed architecture.

In preferred embodiments, parsing and normalization are followed by validity check 210. The validity check may determine whether the identifier resolves unambiguously to a supported fermion or supported classification state. If the identifier resolves cleanly, the parsed and normalized result may be passed forward for sector determination 206 and generation determination 208. If the identifier is unsupported, incomplete, or ambiguous, the system may return unsupported or ambiguous input return 220 rather than proceed with an indeterminate mass assignment. This validity gating preserves the deterministic character of the disclosed architecture by ensuring that fixed torsion, rung, and yardstick operations are applied only to resolved inputs.

In some embodiments, the parsing stage may additionally determine whether the received identifier belongs to a core charged-fermion path or to an enabled extension path. For example, if the input is associated with a neutrino-related extension, boson-related extension, or hypothetical higher-rung extension, the parser may flag the request for separate extension handling when such functionality is present. In the preferred embodiments disclosed herein, however, the canonical charged-fermion path remains the primary path, and extension routing does not alter the core charged-fermion identifier-to-index-to-mass architecture.

The output of identifier normalization and parsing is therefore a resolved internal representation suitable for deterministic classification. In preferred embodiments, that output may include a canonical species record 222 or equivalent internal object containing enough information to proceed to sector determination 206, generation determination 208, generation torsion lookup 212, and sector baseline lookup 214. Whether the original input was a name, symbol, alias, token, structured record, or direct classification input, the normalization and parsing stage serves to deliver a resolved input state that can be processed by the fixed ladder-index and mass-evaluation rule described below.

After a fermion identifier has been normalized or otherwise resolved into a usable internal representation, the disclosed architecture determines the sector S and generation g associated with the requested fermion. Sector and generation determination provide the classification inputs used by the fixed generation torsion assignment, fixed rung assignment, fixed sector yardstick determination, and resulting mass evaluation. Once sector S and generation g have been determined for a supported fermion, subsequent processing under the disclosed architecture is deterministic.

As shown in FIG. 2, sector determination may be performed at step 206 and generation determination may be performed at step 208. In preferred embodiments, these determinations are made from a canonical species representation produced by the identifier normalization and parsing stage described above. In other embodiments, sector S and generation g may be supplied directly as input fields, in which case the determination stage may validate those supplied values rather than infer them from a species name or symbol. In either case, the purpose of this stage is to establish the classification state required for the fixed identifier-to-index-to-mass rule.

In canonical embodiments described herein, the supported sectors include at least a lepton sector, an up-quark sector, and a down-quark sector. In certain embodiments, an electroweak reference sector or another reference or extension sector may also be defined. The sector determination stage identifies which sector-specific fixed constants, baseline rung structure, and yardstick rules will be used in later stages of the computation. Thus, sector determination is not merely descriptive metadata; it is an operative input to the disclosed mass-generation architecture.

In canonical embodiments described herein, the generation index g is one of three values corresponding to a first generation, a second generation, or a third generation. In a preferred representation, these are denoted g=0, g=1, and g=2. The generation determination stage identifies which fixed generation torsion value will be used during the subsequent torsion assignment stage. Thus, generation determination likewise serves as an operative input to the fixed rung-assignment rule.

In one class of embodiments, sector and generation are determined by looking up a canonical species record generated during parsing. For example, a canonical species associated with a charged lepton may resolve to the lepton sector and to a corresponding generation index, while a canonical species associated with an up-type quark or down-type quark may resolve to the corresponding quark sector and generation index. In another class of embodiments, sector and generation are explicitly supplied in a structured input object, and the system validates that the supplied classification is supported before proceeding. Both approaches are compatible with the disclosed fixed identifier-to-index-to-mass rule.

In preferred embodiments, the determination stage includes a validation operation to confirm that the resolved or supplied sector and generation values correspond to a supported category in the invoked embodiment. For example, if a request is directed to a charged-fermion core embodiment, the system may verify that the determined sector and generation correspond to a supported charged-lepton, up-quark, or down-quark category before continuing. If the classification is unsupported, incomplete, or inconsistent, the system may return an unsupported or ambiguous input output rather than proceed with fixed torsion and rung assignment on an indeterminate basis. This validation step is consistent with validity check 210 shown in FIG. 2.

In some embodiments, sector and generation determination may also be used to route a request between a core charged-fermion path and an enabled extension path. For example, if the resolved classification corresponds to a category handled by a separate neutrino module, boson extension, or higher-rung extension, the request may be directed to that separate extension path when such a path is enabled. In preferred embodiments of the present disclosure, however, the primary path is the charged-fermion core path, and extension routing remains subordinate to that core architecture. The use of extension routing does not alter the fixed sector, fixed torsion, fixed rung, and fixed mass-law structure of the charged-fermion core embodiment.

The output of this stage is a resolved and validated classification state comprising at least sector S and generation g. In preferred implementations, the resolved classification state may be stored in a canonical species record 222 or an equivalent internal representation and then passed to generation torsion lookup 212 and sector baseline lookup 214, as shown in FIG. 2. Once sector S and generation g are available, the system can apply the fixed generation torsion values and fixed sector baseline structure disclosed herein to assign a species rung r_f.

Accordingly, sector and generation determination form the classification bridge between input identification and fixed ladder-index assignment. This stage ensures that later mass computation proceeds from resolved, supported, and validated particle-classification information rather than from ad hoc species-specific mass entries. In that respect, sector and generation determination are central operative stages in the disclosed identifier-to-index-to-mass architecture.

After sector S and generation g have been determined, the disclosed architecture assigns a generation torsion value tau(g) corresponding to the resolved generation. In the canonical implementation disclosed herein, generation torsion is fixed and is not selected, tuned, or fitted on a species-by-species basis. Rather, generation torsion is determined directly from the generation index according to a fixed mapping that forms part of the disclosed identifier-to-index-to-mass rule.

In the canonical embodiment, generation torsion is assigned according to:
tau(0)=0
tau(1)=11
tau(2)=17

These values are fixed in the disclosed architecture and are used in subsequent species-rung assignment. Thus, once generation g has been resolved, the corresponding generation torsion value is determined without optimization, interpolation, fitting, or empirical species-specific adjustment.

As shown in FIG. 1, generation torsion module 106 receives the resolved classification information and participates in the fixed ladder-index assignment process. As shown in FIG. 2, generation torsion lookup 212 may be performed after sector determination 206 and generation determination 208. In preferred embodiments, lookup 212 is implemented as a direct mapping from generation value to torsion value, although any equivalent deterministic implementation may be used so long as the disclosed fixed torsion assignment is preserved.

The generation torsion value functions as an operative integer input to species-rung assignment. In canonical embodiments, tau(g) is combined with a fixed sector baseline rung to determine the species rung r_f. As a result, generation torsion is not merely descriptive metadata; it is part of the fixed computational structure by which the disclosed architecture converts classification information into a mass-generating ladder position.

In preferred implementations, the system may validate that the resolved generation is one of the supported canonical generation values before performing the torsion assignment. If the generation value is unsupported in the invoked embodiment, the system may return an unsupported-classification or unsupported-input condition rather than proceed. In canonical charged-fermion embodiments, however, the supported generations are the disclosed generation values g=0, g=1, and g=2, and each such value maps directly to one of the fixed torsion values set forth above.

In embodiments where classification information is supplied directly, generation torsion assignment may occur immediately after validation of the supplied generation value. In embodiments where the classification information is derived from a canonical species identifier, generation torsion assignment may occur after parsing and classification resolution. In either case, the same fixed torsion mapping is used. This preserves the deterministic character of the architecture across different input embodiments.

In some extension embodiments, a separate module may define additional generation-related or ladder-related logic for non-canonical categories. Such extension logic, where present, does not alter the canonical charged-fermion generation torsion assignment disclosed herein. For the charged-fermion core architecture, the fixed torsion values above remain the operative torsion assignments used in rung computation and mass evaluation.

The output of the generation torsion assignment stage is therefore an assigned torsion integer tau(g) associated with the resolved fermion. In preferred embodiments, that torsion value is passed to the rung-assignment stage together with the resolved sector S. Once tau(g) has been assigned, the system can combine that fixed torsion value with a fixed sector baseline rung to determine the species rung r_f used in the disclosed mass law.

Because the generation torsion values are fixed and are used directly in the ladder-index computation, this stage provides an important fallback position for claim drafting. In particular, the fixed mapping tau(0)=0, tau(1)=11, and tau(2)=17 supports dependent claim positions directed to the canonical generation-torsion rule, and further supports the deterministic and parameter-free character of the overall disclosed mass-generation architecture.

After generation torsion tau(g) has been assigned, the disclosed architecture assigns a species rung r_f by combining the fixed generation torsion value with a fixed sector baseline rung. In the canonical implementation disclosed herein, the species rung is assigned according to:

r_f=r_base(S)+tau(g)
where r_base(S) denotes a fixed sector baseline rung associated with sector S, and tau(g) denotes the fixed generation torsion value associated with generation g. Thus, once sector S and generation g have been resolved, the resulting species rung assignment is deterministic.

The sector baseline rung is an operative sector-specific integer used to anchor the ladder position for fermions in a given sector. The generation torsion value provides the generation-dependent offset from that sector baseline. In this way, the disclosed architecture does not assign species rungs as independent fitted values on a particle-by-particle basis. Instead, the rung assignment is generated from fixed sector structure and fixed generation structure. The rung assignment therefore forms a central part of the disclosed identifier-to-index-to-mass rule.

As shown in FIG. 1, sector baseline module 108 and rung assignment module 110 cooperate to assign the species rung after sector and generation information have been resolved and after generation torsion has been assigned. As shown in FIG. 2, sector baseline lookup 214 and rung computation step 216 provide one preferred implementation path for this process. Any equivalent deterministic implementation may be used, provided that the fixed baseline-plus-torsion rule is preserved.

In canonical charged-fermion embodiments, the fixed baseline and torsion structure yield canonical rung assignments for charged leptons, up-type quarks, and down-type quarks. In a canonical charged-fermion embodiment, the fixed sector baseline r_base(S) is defined, by way of example, as r_base(Lepton)=2 for the lepton sector, r_base(UpQuark)=4 for the up-quark sector, and r_base(DownQuark)=4 for the down-quark sector. With these canonical baselines and with the canonical generation torsion values tau(0)=0, tau(1)=11, and tau(2)=17, the resulting canonical rungs for charged fermions are deterministically produced by r_f=r_base(S)+tau(g). In a preferred embodiment, the charged-lepton sector rung assignments include:
r(e)=2
r(mu)=2+tau(1)=13
r(tau)=2+tau(2)=19

In a preferred up-quark embodiment, the rung assignments include:
r(u)=4
r(c)=4+tau(1)=15
r(t)=4+tau(2)=21

In a preferred down-quark embodiment, the rung assignments include:
r(d)=4
r(s)=4+tau(1)=15
r(b)=4+tau(2)=21

These canonical assignments provide a concrete charged-fermion implementation of the disclosed rung-assignment rule.

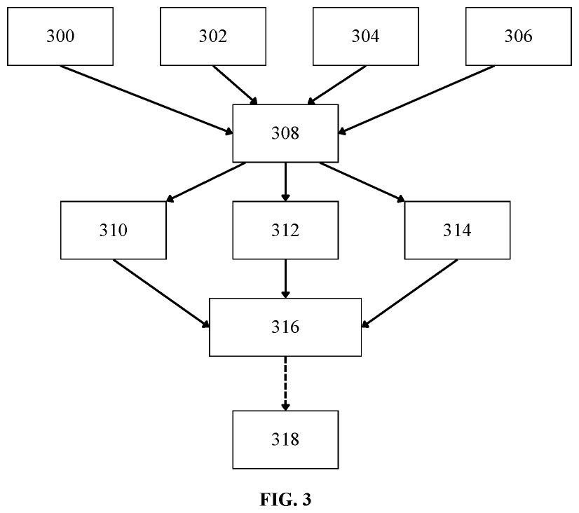

As shown in FIG. 3, the disclosed fixed sector and rung architecture may be represented using lepton sector block 300, up-quark sector block 302, down-quark sector block 304, fixed generation torsion values 308, lepton baseline rung values 310, up-quark baseline rung values 312, down-quark baseline rung values 314, and charged-fermion canonical table 316. FIG. 3 thus illustrates how sector-specific baseline structure and fixed generation torsion values combine to yield canonical charged-fermion rung assignments.

In preferred embodiments, once the species rung r_f has been assigned, the system may additionally compute a preferred baseline-relative half-step index n_L according to:

n_L=2*(r_f−r_base(S))

This half-step index is a preferred representation of ladder position and may be used for output, ratio computation, or display purposes. However, the half-step index is not required to perform the core rung assignment itself. The core rung assignment is completed once r_f has been determined from the fixed baseline-plus-torsion rule.

Because the rung assignment is generated from resolved sector and generation information using fixed mappings, no ranking, balancing, or optimization tie-break rule is needed at this stage. Once the sector S and generation g are known, and the corresponding fixed generation torsion and fixed sector baseline are available, the species rung is uniquely determined. This is one reason the disclosed architecture preserves deterministic behavior from identifier resolution through mass evaluation.

In some embodiments, the system may validate that the resolved sector corresponds to a supported sector baseline structure before performing rung assignment. If the resolved sector is unsupported in the invoked embodiment, the system may return an unsupported-classification output rather than proceed. In preferred charged-fermion embodiments, however, the rung-assignment stage operates directly on the disclosed lepton, up-quark, and down-quark sectors using the fixed baseline-plus-torsion rule described above.

The output of the present stage is therefore a species rung integer r_f associated with the requested fermion. In preferred embodiments, the assigned rung may be included in a structured output record, used to compute a preferred half-step index, used to generate exact intra-sector ratio outputs, or passed directly to the mass-evaluation stage. Once r_f has been assigned, the system can combine that rung with a fixed sector yardstick to generate the fermion mass according to the disclosed phi-based mass law.

This stage also supports important fallback claim positions. In particular, the fixed rule r_f=r_base(S)+tau(g), together with the canonical charged-fermion rung assignments disclosed above, supports narrower claims directed to the charged-fermion embodiment, sector-subset embodiments, and canonical rung-based implementations of the disclosed mass-generation architecture.

After the species rung r_f has been assigned, the disclosed architecture determines a fixed sector yardstick associated with the resolved sector S. The sector yardstick provides the sector-specific mass-scale component used in the disclosed mass law and is combined with the assigned species rung to generate the fermion mass. In the canonical implementation disclosed herein, the sector yardstick is not selected on a particle-by-particle basis and is not fitted independently for each species. Instead, the sector yardstick is determined from fixed sector constants associated with the resolved sector.

In the canonical embodiment, the sector yardstick is defined as:

m_yard(S)=(2\hat{ }(B_pow(S))*phi\hat{ }(−5)*phi\hat{ }(r0(S)))/10\hat{ }6
where B_pow(S) and r0(S) are fixed sector constants for sector S, and phi is the golden ratio.

Thus, once sector S has been resolved, the corresponding sector yardstick is determined from fixed sector structure and does not depend on any per-species fitted mass parameter. The sector yardstick therefore provides the fixed sector-scale input to the subsequent mass-evaluation stage.

As shown in FIG. 1, sector yardstick module 112 receives the resolved sector information and determines the sector yardstick used by mass-evaluation module 114. As shown in FIG. 3, the fixed sector-constant architecture may be represented by lepton sector block 300, up-quark sector block 302, down-quark sector block 304, and electroweak reference block 306. These blocks illustrate that different supported sectors may use different fixed sector constants while still participating in the same overall identifier-to-index-to-mass architecture.

In canonical embodiments described herein, fixed sector constants are provided for at least the lepton sector, the up-quark sector, and the down-quark sector. In certain embodiments, an electroweak reference sector may also be defined. By way of example, the disclosed materials identify canonical sector constants for these sectors and use those constants in computing the corresponding sector yardsticks. The sector yardstick stage therefore establishes the sector-specific portion of the mass computation before species-rung dependence is applied.

In a canonical charged-fermion implementation, the fixed sector constants include, by way of example: (i) for a lepton sector, B_pow(Lepton)=−22 and r0(Lepton)=62; (ii) for an up-quark sector, B_pow(UpQuark)=−1 and r0(UpQuark)=35; (iii) for a down-quark sector, B_pow(DownQuark)=23 and r0(DownQuark)=−5; and (iv) for an electroweak reference sector, B_pow(Electroweak)=1 and r0(Electroweak)=55. These canonical sector-constant values are used to determine m_yard(S) in embodiments that generate a charged-fermion table and related outputs.

In preferred implementations, once sector S has been resolved and validated, the system retrieves or computes the corresponding fixed sector constants B_pow(S) and r0(S), and then computes the sector yardstick m_yard(S) according to the expression above. In some embodiments, the yardstick may be computed directly at runtime. In other embodiments, one or more yardstick values may be precomputed and stored for later use. Whether computed on demand or retrieved from a precomputed representation, the disclosed sector yardstick remains derived from the same fixed sector constants and the same disclosed yardstick law.

The sector yardstick serves as an operative component of the mass-generation architecture rather than as an informational label. Once determined, it is combined with the species rung r_f in the mass-evaluation stage to generate the fermion mass according to:

m_f=m_yard(S)*phi\hat{ }(r_f)

Accordingly, the sector yardstick bridges fixed sector structure and rung-dependent ladder position in the disclosed mass law. The yardstick is therefore central to the deterministic character of the architecture.

In some embodiments, the system may validate that the resolved sector corresponds to a supported set of fixed sector constants before proceeding. If the sector does not correspond to a supported sector-yardstick embodiment in the currently invoked path, the system may return an unsupported-classification output or may route the request to a separate extension embodiment, where enabled. In preferred charged-fermion embodiments, however, the system uses the disclosed fixed sector constants for the lepton, up-quark, and down-quark sectors and proceeds directly to mass evaluation once the corresponding yardstick has been determined.

In certain embodiments, the system may also expose the sector yardstick as part of a structured output record, an internal debugging or verification output, or a precomputed sector data structure. For example, a structured output may include sector S, generation g, assigned rung r_f, sector yardstick m_yard(S), and generated mass m_f. Such output embodiments may be useful in validation, traceability, and product/output claim support, but the operative use of the sector yardstick remains its role in the mass computation itself.

The output of the present stage is therefore a determined sector yardstick m_yard(S) associated with the resolved sector. Once the sector yardstick has been determined, the system can combine that yardstick with the assigned species rung r_f to evaluate the fermion mass according to the disclosed phi-based law. This stage also supports important fallback claim positions directed to architectures in which a fixed sector yardstick is determined from fixed sector constants and then combined with a rung-dependent phi power to generate a fermion mass.

After the sector yardstick m_yard(S) and the species rung r_f have been determined, the disclosed architecture computes the fermion mass according to a fixed phi-based mass law. In the canonical implementation disclosed herein, the mass evaluation is performed deterministically from the fixed sector yardstick and the assigned rung, without per-species fitted mass parameters. Thus, once sector S, generation g, generation torsion tau(g), species rung r_f, and sector yardstick m_yard(S) have been resolved and determined, the corresponding fermion mass follows directly from the disclosed rule.

In a canonical embodiment, the mass evaluation is expressed as:

m_f=m_yard(S)*phi\hat{ }(r_f)
where m_f is the generated mass for fermion f, m_yard(S) is the fixed yardstick associated with sector S, phi is the golden ratio, and r_f is the assigned species rung. This compact form emphasizes that the disclosed architecture separates the fixed sector-scale contribution from the rung-dependent phi-ladder contribution.

In an equivalent canonical form, the mass evaluation may be expressed as:

m_f=(2\hat{ }(B_pow(S))*phi\hat{ }(−5)*phi\hat{ }(r0(S))*phi\hat{ }(r_f))/10\hat{ }6
where B_pow(S) and r0(S) are fixed sector constants. This equivalent form may be useful where the system computes the generated mass directly from the fixed sector constants rather than first forming an intermediate yardstick value. Both forms implement the same disclosed mass-generation architecture.

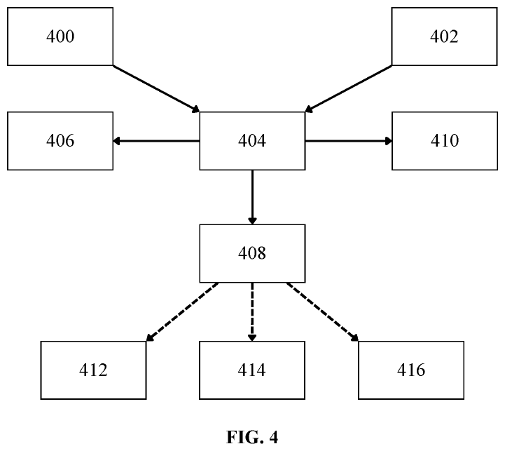

As shown in FIG. 1, mass-evaluation module 114 receives the output of sector yardstick module 112 and the assigned species rung from rung assignment module 110, and computes the resulting fermion mass. As shown in FIG. 4, the disclosed architecture may be represented using full mass-law equation block 400, yardstick equation block 402, and compact mass-evaluation block 404. These figure elements illustrate preferred ways of representing the same operative mass law. In preferred implementations, the mass evaluation may be performed directly in power form by computing phi\hat{ }(r_f) and multiplying the resulting factor by the sector yardstick. In other implementations, the mass evaluation may be performed in logarithmic form. A preferred logarithmic form is:

ln(m_f)=(B_pow(S)*ln 2)+(r0(S)+r_f−5)*ln(phi)−ln(10\hat{ }6)

m_f=exp(ln(m_f))

The logarithmic form may be useful in implementations that prefer precomputed logarithmic constants, numerical stability, or efficient repeated evaluation across multiple species. The use of such a logarithmic form does not alter the disclosed mass law; it is an equivalent implementation form of the same mass-generation rule.

In some embodiments, the disclosed architecture may use double-precision arithmetic, precomputed values of ln(phi), precomputed yardstick values, or precomputed sector constants. In other embodiments, table-lookup or hybrid computation strategies may be used. These are implementation details of the mass-evaluation stage and do not alter the underlying identifier-to-index-to-mass rule. In all such embodiments, the mass remains generated from fixed sector structure and fixed rung assignment rather than from species-specific mass fitting.

In preferred embodiments, the system may produce a mass-only output immediately after mass evaluation. In other embodiments, the generated mass may be included in a structured output record together with sector, generation, torsion value, species rung, half-step index, yardstick value, or related metadata. In still other embodiments, the generated mass may be inserted into a multi-species table, a charged-fermion table, a sector-subset table, or a precomputed machine-readable table. These output modes are downstream consequences of the mass-evaluation stage and do not change the operative mass law used to produce m_f.

In preferred charged-fermion embodiments, the mass-evaluation stage is repeated for multiple canonical species to generate a charged-fermion mass table. In sector-subset embodiments, the same evaluation rule may be applied to only a selected subset of supported fermions, such as only leptons, only up-type quarks, or only down-type quarks. In single-species embodiments, the mass-evaluation stage may be applied only once for one resolved fermion identifier. These are all embodiments of the same disclosed mass-evaluation architecture.

The mass-evaluation stage may also support preferred internal consistency properties of the disclosed architecture. For example, because the mass law is based on a fixed sector yardstick and a phi-power of the species rung, the generated mass is positive for supported inputs, and increasing rung corresponds to increasing mass within a common sector. In addition, exact intra-sector ratio identities may be produced as described in greater detail below. These properties are preferred structural consequences of the disclosed architecture and are supported separately from empirical benchmark material.

In preferred implementations, the system may apply one or more acceptance checks at or after the mass-evaluation stage. By way of example, the system may verify that a supported input produced a valid sector, a valid generation, a valid rung, and a positive mass output. In a table-generation embodiment, the system may verify that all requested supported entries were evaluated successfully. Such checks may improve robustness of implementation but do not alter the disclosed mass law itself.

The output of the present stage is therefore a generated fermion mass m_f determined from fixed sector structure and fixed ladder-index assignment. This stage supports important claim positions directed to single-species mass generation, charged-fermion mass generation, sector-subset mass generation, and mass-only output embodiments. It also supports fallback positions directed to equivalent evaluation forms, including direct yardstick-times-phi-power evaluation and logarithmic evaluation forms implementing the same fixed architecture.

In preferred embodiments, the disclosed mass-generation architecture further provides ratio outputs and half-step outputs derived from the same fixed sector-yardstick and rung-assignment structure used to generate fermion masses. These outputs are preferred consequences and preferred representations of the disclosed architecture. They are not required to practice the core identifier-to-index-to-mass rule, but they provide useful additional structure, output modes, and fallback claim support.

Because the disclosed mass law expresses a fermion mass as a sector yardstick multiplied by a phi power of the assigned rung, exact intra-sector ratio identities may be generated for fermions within a common sector. In a preferred embodiment, for two fermions f and g within the same sector, the system may compute:

m_f/m_g=phi\hat{ }(r_f−r_g)
where r_f and r_g are the assigned species rungs of fermions f and g, respectively. In this form, the sector yardstick cancels, and the resulting ratio depends only on the rung difference within the common sector. This is a preferred exact output relation of the disclosed architecture and distinguishes the architecture from an independent species-by-species lookup approach.

In preferred implementations, a ratio output may be produced in response to an explicit ratio request, or may be generated automatically as part of a structured output record or table output. For example, the system may receive identifiers for two fermions in a common sector, resolve the corresponding sector, generation, torsion values, and rungs, and then output the exact phi-ratio relation between their generated masses. In other embodiments, ratio outputs may be included as annotations in a charged-fermion table or sector-subset table.

As shown in FIG. 4, exact ratio identity block 410 may represent this preferred output mode. In some embodiments, ratio output may be delivered as a symbolic relation, a numerical value, a structured record including both, or another machine-readable representation. The particular output formatting used for the ratio does not alter the underlying identity, which follows directly from the disclosed mass law for fermions within a common sector.

In further preferred embodiments, the disclosed architecture provides a half-step representation of ladder position. In a canonical preferred form, the half-step index n_L is defined as:

n_L=2*(r_f−r_base(S))
where r_f is the assigned species rung and r_base(S) is the sector baseline rung. Under this representation, the baseline species in a given sector may be assigned n_L=0, and other species in the same sector are represented by their baseline-relative half-step positions.

Using the preferred half-step representation, the mass law may be expressed as:

m_f=m_base(S)*phi\hat{ }(n_L/2)
where m_base(S) denotes the mass associated with the baseline species for sector S. In this preferred form, a two-step increase in n_L corresponds to multiplication by phi, giving the preferred identity:

m_(n_L+2)/m_(n_L)=phi

This representation may be useful in implementations that prefer a sqrt(phi) ladder view, baseline-relative reporting, or explicit display of half-step spacing within a sector.

In some embodiments, the system may compute both the species rung r_f and the half-step index n_L and include both values in a structured output record. In other embodiments, the system may output only the half-step index, only the rung, or neither, depending on the requested output mode. Thus, half-step outputs and ratio outputs are preferred output embodiments of the disclosed architecture, but they are not mandatory features of every implementation. The core architecture remains the fixed identifier-to-index-to-mass rule described above.

In preferred charged-fermion embodiments, the ratio and half-step outputs may be particularly useful for table generation and table analysis. For example, a structured charged-fermion output may include sector, generation, torsion value, species rung, half-step index, mass, and one or more ratio relations relative to another species in the same sector. In sector-subset embodiments, such outputs may be limited to a selected sector while preserving the same internal ratio and half-step structure.

The ratio and half-step outputs may also serve as internal consistency outputs, validation-support outputs, or user-facing explanatory outputs. For example, the system may report that two fermions share a common sector and that their generated masses differ by a phi power corresponding to the difference in their assigned rungs. Likewise, the system may report the half-step spacing of a given species relative to the baseline species for that sector. These outputs may improve traceability and interpretability of the generated mass values while remaining subordinate to the core mass-evaluation architecture.

As shown in FIG. 4, half-step equation block 408 and exact ratio identity block 410 illustrate preferred embodiments of these outputs. In implementations using fallback output modes, the system may also provide mass-only output 412, structured-record output 414, or precomputed-table output 416 without requiring ratio or half-step outputs. Thus, FIG. 4 illustrates that ratio and half-step outputs are preferred but non-mandatory embodiments built upon the same fixed computational core.

This section supports important fallback claim positions. In particular, it supports dependent claims directed to exact intra-sector ratio outputs, dependent claims directed to half-step index outputs, dependent claims directed to baseline-relative ladder representations, and dependent claims directed to systems that provide symbolic or numerical ratio relations in addition to generated masses. These preferred outputs strengthen the patent by preserving additional exact structure without converting that additional structure into a required limitation of the core method.

A preferred and concrete implementation of the disclosed mass-generation architecture is a canonical charged-fermion embodiment in which the fixed identifier-to-index-to-mass rule is applied to charged leptons, up-type quarks, and down-type quarks. This embodiment provides the strongest presently disclosed operational example of the architecture because it combines fixed generation torsion values, fixed sector baseline structure, fixed sector constants, fixed rung assignments, and fixed mass evaluation into a complete multi-species table-generation workflow. The charged-fermion embodiment is therefore a preferred implementation of the invention and a principal fallback embodiment for claim support.

In this embodiment, the system receives identifiers for one or more charged fermions, resolves each identifier to a sector S and generation g, assigns a fixed generation torsion value tau(g), assigns a species rung r_f according to the fixed baseline-plus-torsion rule, determines the corresponding fixed sector yardstick, and computes the mass according to the disclosed phi-based mass law. The resulting outputs may be provided individually, as structured records, or collectively as a charged-fermion mass table. Each generated entry is derived from the same fixed architecture and is not treated as an independently fitted species parameter.

In a canonical charged-lepton implementation, the sector baseline and fixed generation torsion values yield the following rung assignments:
r(e)=2
r(mu)=13
r(tau)=19

These assignments follow from the fixed baseline rung for the lepton sector and the fixed torsion values tau(0)=0, tau(1)=11, and tau(2)=17. In preferred embodiments, the corresponding baseline-relative half-step indices may also be reported, with the baseline charged lepton assigned n_L=0 and higher-generation charged leptons assigned corresponding positive half-step values.

In a canonical up-quark implementation, the sector baseline and fixed generation torsion values yield the following rung assignments:
r(u)=4
r(c)=15
r(t)=21

In a canonical down-quark implementation, the sector baseline and fixed generation torsion values yield the following rung assignments:
r(d)=4
r(s)=15
r(b)=21

These canonical quark assignments are likewise generated from the fixed sector baseline structure and fixed generation torsion mapping rather than from independent species-by-species mass fitting.

As shown in FIG. 3, the canonical charged-fermion embodiment may be represented using lepton sector block 300, up-quark sector block 302, down-quark sector block 304, fixed generation torsion values 308, lepton baseline rung values 310, up-quark baseline rung values 312, down-quark baseline rung values 314, and charged-fermion canonical table 316. In preferred embodiments, optional half-step baseline markers 318 may also be shown to indicate baseline-relative ladder positions for one or more sectors. FIG. 3 therefore illustrates how the disclosed fixed sector and generation architecture yields a concrete charged-fermion table embodiment.

In one preferred table-generation embodiment, the system generates a charged-fermion table including at least the following entries: electron, muon, tau, up quark, charm quark, top quark, down quark, strange quark, and bottom quark.

For each entry, the system may provide one or more of: sector, generation, torsion value, species rung, optional half-step index, generated mass, and optional ratio information. In other embodiments, the system may generate only a sector subset, such as only the charged leptons, only the up-type quarks, or only the down-type quarks, while using the same core architecture.

In preferred implementations, the charged-fermion embodiment may use the disclosed fixed sector constants for the lepton, up-quark, and down-quark sectors, and then compute masses according to:

m_f=m_yard(S)*phi\hat{ }(r_f)
or equivalently:

m_f=(2\hat{ }(B_pow(S))*phi\hat{ }(−5)*phi\hat{ }(r0(S))*phi\hat{ }(r_f))/10\hat{ }6

Accordingly, the charged-fermion embodiment is not a separate mass law for each particle. Rather, it is a concrete multi-species implementation of the same disclosed identifier-to-index-to-mass rule.

In preferred embodiments, the charged-fermion table may be generated on demand from supplied identifiers, generated from a canonical requested set, or precomputed and stored in a machine-readable table while remaining derived from the same fixed architecture. A precomputed charged-fermion table may be output through a mass-table interface, a structured export format, or a storage medium. Such precomputed embodiments do not change the disclosed rung assignments, yardsticks, or mass law; they merely change when and how the resulting outputs are materialized.

In some embodiments, the charged-fermion table may additionally include preferred exact ratio relations or half-step outputs. For example, the system may report exact intra-sector phi-ratio relations among charged leptons, among up-type quarks, or among down-type quarks. Likewise, the system may report baseline-relative half-step indices for each sector. These preferred outputs may improve traceability and usefulness of the charged-fermion embodiment, but the core embodiment remains the deterministic generation of charged-fermion masses from fixed sector and generation structure.

In benchmark or demonstrated examples, the charged-fermion embodiment may further be associated with runtime, throughput, or comparison data. Such benchmark data may be useful for demonstrating implementation feasibility or downstream utility, but they do not define the canonical charged-fermion embodiment itself. Likewise, numeric table values may be presented as generated outputs or benchmark summaries for common reference scales without converting those specific display values into mandatory claim limitations.

The canonical charged-fermion embodiment therefore provides a preferred and concrete make-and-use disclosure for the present invention. It supports single-species generation, sector-subset generation, charged-fermion full-table generation, structured outputs, precomputed tables, and preferred ratio and half-step outputs, all while remaining grounded in the same fixed identifier-to-index-to-mass architecture disclosed herein. This section correspondingly supports important fallback claim positions directed to charged-fermion-only implementations, sector-subset implementations, canonical rung-based implementations, and precomputed charged-fermion table embodiments.

The disclosed mass-generation architecture may provide generated results in a variety of output forms while preserving the same underlying identifier-to-index-to-mass rule. In preferred embodiments, the output may be a mass-only output, a structured single-species record, a multi-species table, a ratio output, a precomputed machine-readable table, or another data structure derived from the same fixed sector, torsion, rung, yardstick, and mass-evaluation architecture. The choice of output format does not alter the disclosed mass law or the fixed assignments by which the mass is generated.

In one embodiment, the system provides a mass-only output. A mass-only output contains a generated fermion mass value m_f without requiring additional metadata. This embodiment may be useful where a calling process requires only the generated mass and does not require disclosure of intermediate values such as sector, generation, torsion, rung, half-step index, or sector yardstick. A mass-only output is therefore one preferred reduced-output embodiment of the disclosed architecture. As shown in FIG. 4, mass-only output block 412 represents one example of this output mode.

In another embodiment, the system provides a structured single-species output record. A structured single-species output record may include a generated mass together with one or more associated data fields, including by way of example a canonical species label, sector S, generation g, generation torsion tau(g), species rung r_f, optional half-step index n_L, sector yardstick m_yard(S), or one or more ratio relations. In some implementations, a structured output record may also include status information indicating successful resolution and generation. As shown in FIG. 4, structured-record output block 414 represents one preferred structured output embodiment.

In further embodiments, the system provides a multi-species table output. A multi-species table may contain generated entries for multiple supported fermions and may be organized as a charged-fermion full table, a sector-subset table, a request-defined table, or another machine-readable record set. For each entry, the table may include any one or more of mass, sector, generation, torsion value, species rung, optional half-step index, sector yardstick, or ratio information. A charged-fermion full table is one preferred table embodiment. Sector-subset tables, such as lepton-only, up-quark-only, or down-quark-only tables, are additional preferred embodiments derived from the same architecture.

In preferred ratio-output embodiments, the system may provide an output record that includes a relation between masses of two fermions in a common sector, including a symbolic or numerical form of:

m_f/m_g=phi\hat{ }(r_f−r_g)

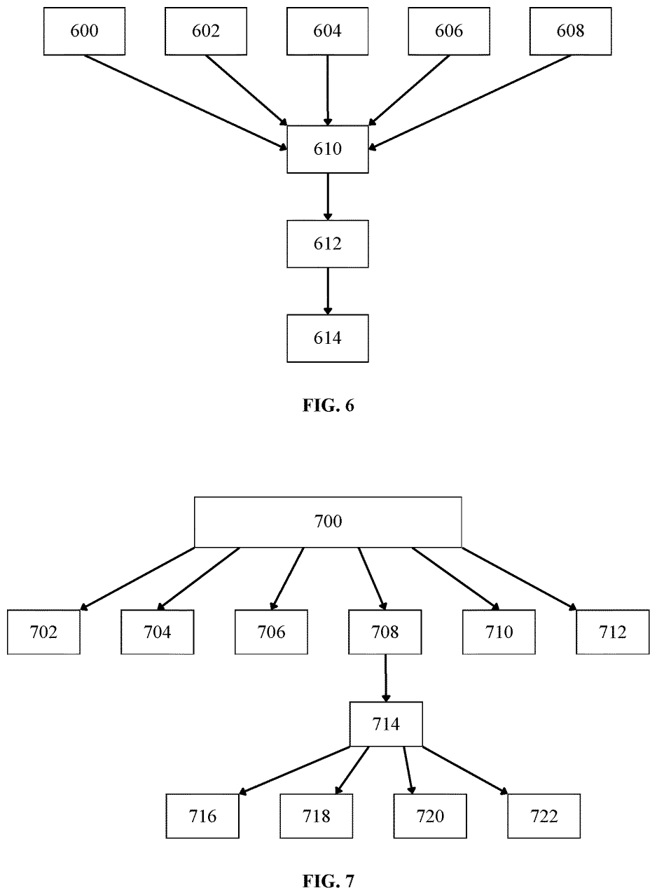

Such a ratio output may be generated as a standalone output or may be embedded in a structured record or table. As shown in FIG. 6, ratio output 608 represents one preferred ratio-output embodiment. The ratio output is derived from the same fixed mass law and is not an independently supplied parameter.

In additional embodiments, the system may generate and store a precomputed machine-readable mass table. A precomputed machine-readable mass table may include one or more generated outputs created in advance and stored in memory or on a non-transitory computer-readable medium for later retrieval. By way of example, the system may precompute a charged-fermion full table, a lepton-sector table, an up-quark-sector table, or another supported output set. As shown in FIG. 4, precomputed-table output block 416 represents one preferred precomputed-table embodiment, and as shown in FIG. 6, precomputed machine-readable table 610 and non-transitory storage medium 612 represent preferred storage-related embodiments. In such embodiments, the stored outputs remain derived from the same disclosed fixed identifier-to-index-to-mass rule.

In some embodiments, the output may be accessed through a retrieval or output interface after storage. For example, a precomputed table may be stored and later queried for one or more entries, or may be exported as a serialized machine-readable file. As shown in FIG. 6, retrieval or output interface 614 represents one such embodiment. The particular storage or retrieval mechanism used is not part of the core invention unless expressly recited; rather, such mechanisms are optional productization embodiments built on top of the disclosed mass-generation architecture.

In certain embodiments, the system may also provide serialized export embodiments. By way of example, a structured record or table may be exported in a textual, binary, or otherwise machine-readable format suitable for downstream use in simulation, validation, or integration workflows. In preferred embodiments, serialization preserves the generated values and associated metadata without altering the fixed sector, torsion, rung, yardstick, or mass law by which those values were obtained. Serialization format is therefore an implementation detail of output handling rather than a change to the disclosed computational architecture.

The system may also provide error or ambiguity outputs. For example, if a received identifier cannot be resolved unambiguously to a supported category, the system may return an unsupported-input or ambiguous-input output instead of returning a generated mass. Likewise, if a requested output format is unsupported for the invoked embodiment, the system may return an error or status output indicating the unsupported request. Such error and ambiguity outputs may be included in a structured output framework without changing the fixed identifier-to-index-to-mass rule used for valid requests.

As shown in FIG. 6, a preferred output-products and storage figure may include mass-only output 600, structured single-species record 602, sector-subset table 604, charged-fermion full table 606, ratio output 608, precomputed machine-readable table 610, non-transitory storage medium 612, and retrieval or output interface 614. FIG. 6 thus illustrates that the disclosed architecture supports multiple product and output embodiments while preserving the same computational core.

This section supports several important claim categories. In particular, it supports claims directed to mass-only outputs, structured output records, multi-species tables, ratio outputs, precomputed charged-fermion tables, machine-readable mass tables, and non-transitory computer-readable media storing instructions or generated outputs derived from the disclosed architecture. These output and product embodiments broaden practical protection while keeping the core invention anchored to the fixed identifier-to-index-to-mass rule.

The disclosed mass-generation architecture may be implemented as a computer-implemented system comprising functional modules that cooperate to receive fermion-identifying information, resolve classification data, assign fixed ladder indices, determine sector yardsticks, compute masses according to the disclosed phi-based law, and provide one or more outputs. The particular partitioning of functionality among software modules, services, libraries, processors, memory elements, or interfaces may vary across implementations. However, in preferred embodiments, the system preserves the same fixed identifier-to-index-to-mass rule regardless of implementation form.

In one preferred embodiment, the system includes an identifier intake module configured to receive a fermion identifier from a user, process, data file, software interface, structured request object, or other input source. The identifier intake module may accept a particle name, symbol, canonical species token, direct sector-and-generation pair, or other machine-readable identifier sufficient to support deterministic resolution into classification data. In some embodiments, the intake module may receive one identifier for single-species generation. In other embodiments, the intake module may receive multiple identifiers for table generation or sector-subset generation.

In a preferred implementation, the system further includes a parser or normalizer configured to canonicalize the received identifier into a standard internal representation. The parser or normalizer may perform canonicalization, alias resolution, token handling, or direct-input validation. As described above, these parsing and normalization operations are preparatory operations that facilitate deterministic downstream processing, but do not alter the fixed torsion values, fixed sector baseline structure, fixed sector constants, or fixed mass law. In FIG. 1, parser or normalizer 102 represents one preferred embodiment of this functionality.

The system further includes a sector and generation resolver configured to determine sector S and generation g associated with the received identifier. In one embodiment, the resolver operates on a canonical species record produced by the parser or normalizer. In another embodiment, the resolver validates sector and generation fields supplied directly by the input. The resolver provides the classification state required for subsequent fixed generation torsion assignment, fixed rung assignment, and fixed sector-yardstick determination. In FIG. 1, sector and generation resolver 104 represents one preferred embodiment of this functionality.

The system further includes a generation torsion module configured to assign a fixed generation torsion value tau(g) from the resolved generation. In the canonical disclosed embodiment, the generation torsion module implements the fixed mapping tau(0)=0, tau(1)=11, and tau(2)=17. The torsion module may be implemented as a lookup table, direct mapping logic, encoded constant set, software routine, or equivalent deterministic mechanism. In FIG. 1, generation torsion module 106 represents one preferred embodiment of this functionality.

The system also includes a sector baseline module and a rung assignment module. The sector baseline module is configured to provide a fixed sector baseline rung r_base(S) corresponding to the resolved sector. The rung assignment module is configured to assign the species rung r_f according to the fixed rule:

r_f=r_base(S)+tau(g)

In some embodiments, the rung assignment module may additionally compute a preferred half-step index n_L. In FIG. 1, sector baseline module 108 and rung assignment module 110 represent preferred embodiments of these functions. Together, these modules convert resolved classification data into the integer ladder position used in the disclosed mass law.

The system further includes a sector yardstick module configured to determine a fixed sector yardstick m_yard(S) from fixed sector constants associated with the resolved sector. In a canonical embodiment, the sector yardstick module implements:

m_yard(S)=(2\hat{ }(B_pow(S))*phi\hat{ }(−5)*phi\hat{ }(r0(S)))/10\hat{ }6

The sector yardstick module may compute the yardstick on demand, retrieve one or more precomputed yardstick values, or use another equivalent deterministic implementation. In FIG. 1, sector yardstick module 112 represents one preferred embodiment of this functionality.

The system further includes a mass-evaluation module configured to compute the generated fermion mass from the fixed sector yardstick and the assigned species rung. In one canonical embodiment, the module implements:

m_f=m_yard(S)*phi\hat{ }(r_f)

In another equivalent embodiment, the module implements the full disclosed mass expression directly from fixed sector constants. In still other embodiments, the mass-evaluation module may use a logarithmic evaluation form, double-precision arithmetic, precomputed constants, or precomputed table values. In FIG. 1, mass-evaluation module 114 represents one preferred embodiment of this functionality.

The system further includes an output formatter configured to provide the generated result in one or more requested output forms. In preferred embodiments, the output formatter may provide a mass-only output, a structured single-species record, a multi-species table, a ratio output, a sector-subset table, or a precomputed machine-readable table. In FIG. 1, output formatter 116 represents one preferred embodiment of this functionality, and single-mass output 118 and mass-table output 120 represent preferred output paths.

In some embodiments, the system may include one or more optional packaging layers. Such packaging layers may include an application programming interface, a language binding, a plugin layer, a retrieval interface, a serialization interface, a storage layer, or another external-access mechanism. These packaging layers may expose the disclosed architecture to external software, data pipelines, or users, but they do not define the core invention. In FIG. 1, optional packaging layer 122 represents one preferred packaging embodiment.

In one class of embodiments, the disclosed architecture may be implemented in software executed by one or more processors using one or more memory devices storing instructions and optionally storing precomputed constants, yardsticks, or tables. In another class of embodiments, the architecture may be implemented as a library, service, callable module, embedded component, or hybrid system. In another class of embodiments, one or more outputs of the system may be stored in a non-transitory computer-readable medium or a machine-readable memory. These implementation forms alter the packaging and deployment of the architecture, but not its underlying fixed computational rule.

In preferred embodiments, the system may additionally include validation logic configured to confirm that a received identifier resolves to a supported classification state, that the resolved generation is supported, that the sector is associated with fixed sector constants, and that the resulting mass computation produces a valid output. Such validation logic may cooperate with the parser, resolver, torsion module, baseline module, yardstick module, and output formatter to preserve deterministic and robust operation across supported embodiments.

As shown in FIG. 1, the preferred system architecture therefore includes input fermion identifier 100, parser or normalizer 102, sector and generation resolver 104, generation torsion module 106, sector baseline module 108, rung assignment module 110, sector yardstick module 112, mass-evaluation module 114, output formatter 116, single-mass output 118, mass-table output 120, and optional packaging layer 122. This arrangement illustrates one preferred system implementation of the disclosed identifier-to-index-to-mass architecture. Equivalent system partitions may be used provided that the disclosed fixed torsion, fixed baseline, fixed sector-constant, and fixed mass-law operations are preserved.

This section supports important system-claim and apparatus-claim positions. In particular, it supports claims directed to systems comprising an intake or resolver module, a torsion and rung assignment module, a sector-yardstick module, a mass-evaluation module, and an output module. It also supports narrower system claims directed to optional packaging layers, precomputed storage embodiments, or table-generation embodiments, while preserving the core invention as the fixed computational architecture itself.

The disclosed mass-generation architecture may be implemented using a variety of computational techniques while preserving the same fixed identifier-to-index-to-mass rule. The implementation details described in this section relate to preferred execution forms, preferred numerical forms, preferred storage forms, and preferred interface forms for carrying out the disclosed architecture. These implementation details do not alter the fixed generation torsion values, fixed sector baseline structure, fixed sector constants, or fixed mass law described above.

In one preferred implementation, the disclosed architecture is executed using software instructions stored in memory and executed by one or more processors. The software may be organized as a library, callable routine, service, local executable, server-side process, embedded computational component, or other machine-executable arrangement. In such embodiments, the system receives a fermion identifier, resolves the identifier into sector and generation information, assigns the fixed torsion and rung values, determines the sector yardstick, computes the mass, and formats the resulting output according to the requested output mode.

In preferred numerical implementations, the mass evaluation may be performed using direct exponentiation of phi or using an equivalent logarithmic form. A preferred logarithmic implementation is:

ln(m_f)=(B_pow(S)*ln 2)+(r0(S)+r_f−5)*ln(phi)−ln(10\hat{ }6)

m_f=exp(ln(m_f))

This form may be useful where repeated evaluation is performed across multiple species, where precomputed logarithmic constants are desired, or where a processor or software environment is optimized for logarithmic and exponential evaluation. In other implementations, the system may compute phi\hat{ }(r_f) directly and multiply by the sector yardstick. Both approaches are implementations of the same disclosed mass law.

In some embodiments, the disclosed architecture may use double-precision arithmetic, precomputed values of ln(phi), precomputed yardstick values, precomputed sector constants, or other intermediate quantities. These are implementation details of the mass-evaluation stage and do not alter the underlying fixed identifier-to-index-to-mass architecture. In all such embodiments, the mass remains generated from fixed sector structure and fixed rung assignment rather than from species-specific mass fitting.

In preferred table-generation embodiments, the system may evaluate the disclosed mass law repeatedly across a requested set of supported fermions. For example, a charged-fermion full table may be produced by evaluating the disclosed mass law for each supported charged lepton and quark in the requested set. In sector-subset embodiments, the same mass law may be evaluated for only a subset of supported fermions, such as only leptons, only up-type quarks, or only down-type quarks. In single-species embodiments, the evaluation may be performed once for one resolved fermion identifier.

In some embodiments, precomputed values may be used to improve performance. By way of example, one or more sector yardsticks may be precomputed, one or more canonical mass entries may be precomputed, or one or more ratio outputs may be precomputed for later retrieval. In such embodiments, the precomputed values remain derived from the same fixed identifier-to-index-to-mass rule and therefore do not replace the disclosed architecture with independent lookup values. A precomputed table may be generated by the disclosed architecture once and then stored for later output, retrieval, or downstream use.

In certain implementations, a table-lookup mode may be used after generation of a precomputed mass table. For example, the system may first compute a canonical charged-fermion table using the disclosed fixed architecture and then, in later requests, retrieve one or more corresponding entries from the stored table. Likewise, a precomputed sector-subset table may be used in place of repeating the full computation for every request. These are implementation optimizations and do not alter the disclosed generation rule itself.

In some embodiments, the output of the system may be serialized into a machine-readable format. A mass-only output, structured single-species record, ratio output, or multi-species table may be represented in textual, binary, or other serialized forms suitable for downstream computational use. In preferred embodiments, the serialized form preserves the generated output values and any requested associated metadata without changing the fixed architecture by which those values were produced.

In certain embodiments, the system may expose the disclosed architecture through one or more optional interface layers. By way of example, the architecture may be accessible through an application programming interface, a callable software library, a local command interface, a batch-generation process, a file-based interface, or another programmatic access path. Such interface embodiments may improve usability or integration but remain optional packaging features rather than the core inventive mechanism.

In some embodiments, the disclosed architecture may be containerized or deployed in a memory-constrained or resource-constrained environment. In other embodiments, the architecture may be deployed as part of a larger simulation framework, compute pipeline, or hardware-assisted environment. The disclosed materials may include benchmark examples relating to runtime, throughput, latency, memory footprint, or image size. These benchmark values may demonstrate one or more working implementations, but should not be treated as required limitations of the disclosed architecture unless expressly claimed.

In preferred implementations, the system may perform one or more acceptance checks during or after execution. For example, the system may verify that a resolved input corresponds to a supported sector and generation, that the corresponding fixed torsion and fixed sector constants were successfully retrieved, that the resulting species rung was assigned, and that the generated mass was positive. In table-generation embodiments, the system may additionally verify that all requested supported entries were generated successfully. Such checks may improve robustness and traceability, but do not alter the fixed identifier-to-index-to-mass rule.

In some embodiments, internal intermediate values may be made available for debugging, tracing, validation, or structured output. By way of example, the system may expose the resolved sector, resolved generation, assigned torsion value, assigned rung, determined yardstick, logarithmic intermediate value, or output formatting state. In other embodiments, the system may expose only the final mass output. These are output and traceability choices layered on top of the same mass-generation architecture.

Where desired, the disclosed architecture may be implemented in a manner that supports repeated high-volume queries, batch generation of mass tables, or generation of precomputed output products for later use. Likewise, the system may be implemented in a manner that supports local execution, remote execution, embedded execution, or another execution environment. These implementation choices affect deployment and performance characteristics, but do not affect the fixed torsion, fixed baseline, fixed sector-constant, and fixed mass-law structure of the disclosed invention.

Accordingly, the implementation details described herein provide preferred make-and-use disclosure for carrying out the mass-generation architecture across different software, storage, and deployment environments while preserving the same underlying fixed computational rule. This section further supports narrower fallback positions directed to logarithmic evaluation, double-precision computation, precomputed yardsticks, precomputed tables, serialization, optional interface embodiments, and other implementation-specific features without converting those features into mandatory limitations of the core invention.

In preferred embodiments, the disclosed mass-generation architecture is supported by machine-checked formalization of selected fixed mathematical properties associated with the identifier-to-index-to-mass rule. Such formal-verification support is technical support for fixed and exact aspects of the disclosed architecture and is distinct from empirical benchmarks, implementation-performance measurements, and prophetic extension embodiments.

In preferred embodiments, the formal support includes machine-checked support for the canonical generation-torsion values, the canonical species-rung assignments, the canonical sector constants, positivity of generated mass values, monotonicity of mass with increasing rung within a common sector, and exact intra-sector phi-ratio behavior. In preferred implementations, these supported properties correspond to machine-checked result categories including support for tau values, support for rung values, support for sector constants, support for mass positivity, support for mass monotonicity, and support for phi-ratio behavior. These supported properties correspond directly to central features of the disclosed architecture, namely: fixed integer assignment from generation and sector structure, fixed sector-yardstick determination, deterministic rung-based mass evaluation, and exact structural relationships among outputs produced within a common sector.

In one preferred embodiment, the disclosed formal support includes machine-checked confirmation of the canonical generation-torsion mapping:
tau(0)=0
tau(1)=11
tau(2)=17
and machine-checked support for canonical charged-fermion rung assignments derived from the fixed baseline-plus-torsion rule, including the canonical charged-lepton, up-quark, and down-quark rung assignments disclosed herein. These fixed assignments are central to the disclosed identifier-to-index-to-mass architecture because they govern the ladder positions from which the generated masses are computed and because they preserve the disclosed architecture as a fixed rule-based generator rather than a species-by-species fitted table.

In another preferred embodiment, the disclosed formal support includes machine-checked support for fixed sector constants used in the sector-yardstick stage. Because the sector yardstick is determined from fixed sector constants and then combined with a rung-dependent phi power to generate a mass, support for the fixed sector constants provides technical grounding for the sector-specific portion of the disclosed mass law.

It should be understood that formal-verification support, where present, is separate from benchmark or validation material such as runtime measurements, throughput measurements, PDG comparison values, lattice-QCD acceptance improvements, or cosmic-ray simulation comparisons. Those benchmark and validation items reflect implementation examples, empirical studies, or demonstrated uses of the disclosed architecture, whereas the formal support described in this section relates to fixed and exact mathematical properties of the disclosed computational rule. This distinction is important because it preserves the difference between exact structural support and empirical implementation evidence.

In additional preferred embodiments, the disclosed formal support includes machine-checked support for monotonicity of generated mass with increasing rung within a common sector. In other words, where the sector yardstick remains fixed and the assigned rung increases, the corresponding generated mass increases as a consequence of the disclosed phi-based law. This monotonicity is a preferred structural property of the disclosed architecture and may be useful for internal consistency analysis, validation support, and prosecution support regarding the determinative nature of the disclosed rule.

In further preferred embodiments, the disclosed formal support includes machine-checked support for exact intra-sector phi-ratio behavior. In particular, for fermions within a common sector, the system may provide or derive the exact relation:

m_f/m_g=phi\hat{ }(r_f−r_g)

Because the sector yardstick cancels in such intra-sector comparisons, this ratio identity follows directly from the fixed rung-based architecture. Machine-checked support for this relation reinforces that the disclosed outputs are not merely independent species entries, but instead arise from a common fixed computational structure.

In certain embodiments, the disclosed formal support may be implemented using a machine-checked theorem-proving or proof-assistance environment. Such an environment may encode one or more definitions, fixed constants, mapping rules, and formal statements corresponding to the architecture described herein. In preferred embodiments, the role of such formal support is to provide technical support for exact and fixed features of the disclosed architecture, including fixed values and exact structural consequences. The role of such formal support is not to replace the make-and-use disclosure of the system, nor to convert empirical or benchmark features into mathematically proven requirements of the invention.

As shown in FIG. 7, disclosed mass-generator architecture 700 may be associated with fixed tau-value support 702, fixed rung-value support 704, fixed sector-constant support 706, positivity support 708, monotonicity support 710, and exact phi-ratio support 712. FIG. 7 thus illustrates one preferred way of presenting formal support for fixed mathematical properties of the disclosed architecture while separating those properties from benchmark and validation branches discussed below.

Accordingly, the present section supports specification leverage for fixed and exact aspects of the disclosed architecture, including fixed generation-torsion values, fixed rung assignments, fixed sector constants, positivity, monotonicity, and exact phi-ratio identities. This support may be cited in prosecution to reinforce the determinative character of these aspects of the disclosure, while avoiding unsupported legal conclusions and without converting empirical benchmark material into mandatory claim limitations.

In preferred embodiments, benchmark and validation material associated with the disclosed mass-generation architecture may be understood in three distinct categories. A first category includes internal validity checks associated with execution of the disclosed architecture, such as successful identifier resolution, supported sector and generation determination, successful fixed torsion and rung assignment, and positive mass generation. A second category includes empirical benchmark and comparison material associated with implemented embodiments, such as runtime, query rate, latency, reference-mass comparison, lattice-QCD example data, or cosmic-ray simulation example data. A third category includes future-facing or predictive material associated with extension embodiments, which is separate from demonstrated benchmark material. This layered treatment preserves a distinction between exact architectural structure, demonstrated implementation evidence, and prophetic material.

In one class of demonstrated embodiments, the disclosed architecture is used to generate single-species mass outputs and charged-fermion table outputs. In such embodiments, the system receives one or more supported fermion identifiers, resolves sector and generation information, assigns fixed torsion and rung values, determines sector yardsticks, computes masses according to the disclosed phi-based law, and outputs the resulting mass values or records. These demonstrated embodiments provide practical make-and-use support for the core computational architecture and for preferred output formats including structured records and full tables.

In another class of demonstrated embodiments, the disclosed implementation is associated with runtime, throughput, latency, or memory-related benchmark values. By way of example, the disclosed materials identify benchmark values for full charged-fermion table generation time, mass-query rate, interface latency, container size, or memory footprint. Such metrics are useful for showing that the disclosed architecture can be implemented efficiently in practical computational environments. These metrics are implementation-specific benchmark values and are not required features of the fixed identifier-to-index-to-mass rule.

In further benchmark embodiments, the disclosed architecture is compared against external mass references or other computational targets. For example, generated masses for selected charged fermions may be compared with commonly used reference values such as PDG values or other standard reference-scale values. In such embodiments, these comparisons are best understood as empirical benchmarks or illustrative comparisons rather than as defining requirements of the disclosed architecture. This is especially important for quark-mass comparisons, which may depend on scale conventions, scheme conventions, or reference conventions external to the fixed identifier-to-index-to-mass rule itself.

In another demonstrated use case, the disclosed architecture is applied in lattice quantum chromodynamics workflows. In such embodiments, generated quark masses may be converted into lattice units and used in connection with initialization of kappa values or related simulation parameters. The disclosed materials further identify benchmark or demonstrated example values relating to acceptance, thermalization, or setup improvement in such workflows. These lattice-related results are useful for demonstrating downstream utility of the disclosed architecture in a realistic computational environment. However, such results remain application benchmarks and do not redefine the core invention, which remains the deterministic mass-generation architecture itself.

In some embodiments, validation additionally includes internal validity checks performed during execution of the disclosed architecture. By way of example, the system may verify that a received identifier resolved unambiguously to a supported category, that sector and generation were determined successfully, that the corresponding fixed torsion and fixed rung values were assigned, that the corresponding sector yardstick was determined, and that the resulting generated mass was positive. In table-generation embodiments, the system may additionally verify that all requested supported entries were generated successfully. These internal validity checks are distinct from empirical benchmark comparisons and provide implementation-level support that the disclosed architecture operated successfully for the requested input set.

As shown in FIG. 7, empirical benchmark branch 714 may include runtime or query benchmark 716, PDG comparison benchmark 718, lattice benchmark 720, and cosmic-ray benchmark 722. FIG. 7 therefore illustrates one preferred way of distinguishing exact structural support for the disclosed mass-generator architecture from demonstrated implementation and application evidence. This distinction preserves a clear separation between fixed mathematical properties of the disclosed architecture, empirical benchmark evidence associated with implemented embodiments, and future-facing predictive material associated with extension embodiments.

In preferred drafting practice, benchmark and validation material should be presented using terms such as benchmark, empirical comparison, demonstrated example, implementation result, target, or validation example. Such material should not be presented as though it were required by the core invention unless a particular benchmark feature is intentionally claimed. For example, runtime values, throughput values, acceptance improvements, flux comparisons, or reference-mass comparisons may all strengthen the practical credibility of the disclosure while still remaining non-mandatory embodiments.

In certain embodiments, benchmark and validation material may also include internal consistency checks, output-verification checks, or implementation-acceptance checks. By way of example, a system may verify that a requested supported input produced a positive mass output, that all requested entries in a table were generated successfully, or that a ratio output matched the exact phi-ratio relation expected from the disclosed architecture. Such internal checks may serve both as implementation-validation tools and as additional support for robust deployment of the architecture.

Accordingly, the benchmark and validation material described herein supports the practical feasibility and demonstrated utility of the disclosed architecture across single-species generation, table generation, and downstream computational uses. At the same time, the benchmark and validation material remains categorically distinct from the fixed mathematical structure of the disclosed identifier-to-index-to-mass rule and from prophetic extension material described elsewhere. This separation preserves clarity in the specification, strengthens prosecution posture, and avoids conflating exact architectural properties with empirical or implementation-specific results.

In certain embodiments, the mass values generated by the disclosed identifier-to-index-to-mass architecture are used in downstream computational workflows. In such embodiments, the disclosed architecture provides generated fermion mass values for use in one or more external systems, simulations, or computational environments. These downstream uses are applications of the generated outputs of the core identifier-to-index-to-mass architecture and do not redefine the invention itself.

In one embodiment, the disclosed mass-generation architecture is used in a lattice quantum chromodynamics workflow. One or more generated quark masses may be provided as inputs to a lattice-QCD initialization process. In a preferred implementation, the generated mass values are converted into lattice units according to:

a*m_q=(m_q(MeV)*a(fm))/(hbar c)
and one or more hopping parameters are initialized according to:

kappa_q=1/(2*(a*m_q+4))
where a denotes lattice spacing, m_q denotes the generated quark mass, and hbar c denotes a conversion factor. In such embodiments, the generated mass values provide deterministic mass inputs for use in lattice initialization.

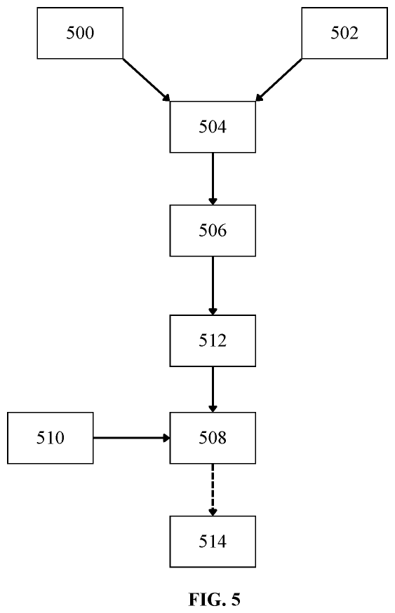

As shown in FIG. 5, one lattice-QCD embodiment may include lattice spacing input 500, generated quark-mass table 502, lattice-unit conversion block 504, kappa computation block 506, and HMC initialization block 508. FIG. 5 may further illustrate a conventional iterative tuning path 510 and a direct-initialization path 512. In such embodiments, the generated mass values are supplied to the downstream lattice workflow after generation by the disclosed mass architecture.

In another embodiment, the disclosed architecture is used in collider-event generation or related high-energy simulation workflows. Generated fermion mass values may be supplied to one or more event generators, matrix-element tools, decay calculators, or related computational modules. The generated masses may be provided as mass-only outputs, structured records, precomputed tables, or machine-readable serialized outputs.

In a further embodiment, the disclosed architecture is used in a cosmic-ray, astroparticle, or related Monte Carlo simulation workflow. One or more generated fermion mass values may be supplied to lepton-propagation, electroweak, or related computational modules. The resulting simulation may then use those generated values in subsequent processing.

In another embodiment, the disclosed architecture is used for cross-code mass standardization. A generated mass table, sector-subset table, or precomputed machine-readable table may be supplied to multiple downstream software environments so that those environments operate from a common set of generated fermion mass values.

In certain embodiments, the disclosed architecture is used in educational, exploratory, or interactive computational environments. A user-facing interface, scripting environment, notebook environment, or command-line interface may call the disclosed mass-generation architecture to obtain single-species outputs, charged-fermion tables, sector-subset tables, ratio outputs, or half-step outputs.

In each of the foregoing embodiments, the generated mass values are produced by the disclosed identifier-to-index-to-mass architecture and are then used in a downstream environment.

In addition to the charged-fermion embodiments described above, the disclosed identifier-to-index-to-mass architecture may be used in alternative and extension embodiments in which the same general index-based mass-generation framework is applied to additional particle categories, additional output regimes, or additional computational contexts.

In one extension embodiment, the disclosed architecture is applied to higher-rung fermion states beyond the canonical charged-fermion set. In such embodiments, one or more additional rung values may be assigned above the canonical charged-fermion rungs, and corresponding masses may be generated using the same phi-based mass law. By way of example, a lepton-sector implementation may assign a higher species rung and compute a corresponding mass from the fixed lepton-sector yardstick and the assigned rung. Such embodiments may be used to generate candidate masses for hypothetical or as-yet-unobserved fermionic states.

In another extension embodiment, the disclosed architecture is applied to boson-related categories. In such embodiments, one or more boson masses may be generated using sector constants and fixed rung assignments defined for a boson or electroweak-related category. The resulting mass generation may use the same general architecture in which a fixed sector structure is combined with a phi-based ladder evaluation. Boson-related embodiments may be implemented as extension modules separate from the canonical charged-fermion path.

In a further extension embodiment, the disclosed architecture is applied to a neutrino-related module. In such embodiments, the architecture may provide integer index assignments, ordering relations, or ladder-style structure for neutrino categories, while absolute neutrino mass scaling is handled by separate extension logic. Thus, a neutrino embodiment may share the disclosed index-assignment style while using a distinct absolute-scaling treatment appropriate to that module.

In another extension embodiment, the disclosed architecture is combined with a scale-dependent transport or running-mass formulation. In such embodiments, a mass generated at one reference point may be transported to another scale using an additional transport relation, renormalization relation, or running-mass approximation. The disclosed identifier-to-index-to-mass architecture may thereby provide a fixed reference-scale mass input to a further scale-dependent processing stage.

In another embodiment, the disclosed architecture is implemented using hardware-oriented storage or hardware-assisted deployment. By way of example, one or more generated mass tables, sector-subset tables, or charged-fermion tables may be stored in a memory device, read-only memory, programmable logic device, application-specific integrated circuit environment, or other hardware-associated storage or retrieval environment. In such embodiments, the generated mass values remain derived from the disclosed fixed computational rule even if later accessed from stored hardware-resident representations.

In some embodiments, alternative input modes may be used. For example, instead of receiving a particle name or symbol, the system may receive a direct sector-and-generation pair, a canonical numeric token, or another structured representation sufficient to determine the corresponding fixed torsion value, fixed rung assignment, and fixed sector yardstick. Likewise, alternative output modes may be used, including symbolic outputs, serialized tables, ratio-focused outputs, half-step outputs, or mixed outputs containing both generated masses and associated intermediate values.

In some embodiments, the system may be configured to enable or disable one or more extension paths selectively. For example, a deployed implementation may enable only the canonical charged-fermion embodiment, may enable charged-fermion and boson embodiments together, or may enable a neutrino-related extension in addition to the charged-fermion core path. Where multiple paths are available, the system may route a request according to the resolved category associated with the received identifier.

In further embodiments, one or more of the described alternative or extension embodiments may be implemented as separate modules that interact with the charged-fermion core architecture through shared identifier-resolution, rung-assignment, output-formatting, or storage interfaces. In such embodiments, the charged-fermion core path may remain available as a default or baseline embodiment while one or more extension modules provide additional functionality.

In embodiments involving hypothetical or predictive states, the disclosed architecture may be used to generate candidate masses for comparison with future experimental, observational, or simulation results. Such predictive embodiments may be used to define candidate search targets, simulation parameters, or comparison values in later studies or analyses.

The foregoing alternative and extension embodiments illustrate that the disclosed identifier-to-index-to-mass architecture may be adapted to additional categories and implementations while retaining its underlying fixed computational structure.

1. A computer-implemented method for generating a fermion mass, the method comprising: receiving a fermion identifier; determining, from the fermion identifier, a sector S and a generation g associated with a fermion; assigning a generation torsion value tau(g) corresponding to the generation g; assigning a species rung r_f from the sector S and the generation torsion value tau(g); determining a sector yardstick m_yard(S) from fixed sector constants associated with the sector S; computing a mass m_f for the fermion according to: m_f=m_yard(S)*phi\hat{ }(r_f) where phi is the golden ratio; and outputting the mass m_f, wherein the mass m_f is generated without per-species fitted mass parameters.

2. The method of claim 1, wherein the generation torsion value tau(g) is assigned according to: tau(0)=0, tau(1)=11, and tau(2)=17.

3. The method of claim 1, wherein the species rung r_f is assigned according to: r_f=r_base(S)+tau(g), where r_base(S) is a fixed sector baseline rung.

4. The method of claim 1, wherein the sector yardstick is determined according to: m_yard(S)=(2\hat{ }(B_pow(S))*phi\hat{ }(−5)*phi\hat{ }(r0(S)))/10\hat{ }6, where B_pow(S) and r0(S) are fixed sector constants associated with the sector S.

5. The method of claim 1, wherein the mass m_f is computed according to: m_f=(2\hat{ }(B_pow(S))*phi\hat{ }(−5)*phi\hat{ }(r0(S))*phi\hat{ }(r_f))/10\hat{ }6.

6. The method of claim 1, further comprising determining a half-step index n_L according to: n_L=2*(r_f−r_base(S)), where r_base(S) is a fixed sector baseline rung.

7. The method of claim 6, wherein the mass is represented according to: m_f=m_base(S)*phi\hat{ }(n_L/2).

8. The method of claim 6, further comprising providing a relation: m(n_L+2)/m(n_L)=phi.

9. The method of claim 1, further comprising generating a ratio output for two fermions within a common sector according to: m_f/m_g=phi\hat{ }(r_f−r_g).

10. The method of claim 1, further comprising generating a structured output record containing the mass m_f and at least one of: the sector S, the generation g, the generation torsion value tau(g), the species rung r_f, a half-step index n_L, or the sector yardstick m_yard(S).

11. The method of claim 1, further comprising generating a multi-species mass table comprising masses for a plurality of supported fermions.

12. The method of claim 11, wherein the multi-species mass table comprises a charged-fermion table.

13. The method of claim 1, wherein the fermion identifier comprises a direct sector-and-generation input, and the method further comprises assigning the species rung r_f without requiring name-based or symbol-based parsing.

14. The method of claim 1, further comprising generating a precomputed machine-readable mass table comprising masses for a plurality of supported fermions, storing the precomputed machine-readable mass table in a non-transitory storage medium, and retrieving at least one mass value from the precomputed machine-readable mass table in response to a subsequent request.

15. A system for generating fermion masses, the system comprising: an input module configured to receive a fermion identifier; a resolver configured to determine, from the fermion identifier, a sector S and a generation g; a generation torsion module configured to assign a generation torsion value tau(g); a rung assignment module configured to assign a species rung r_f from the sector S and the generation torsion value tau(g); a sector yardstick module configured to determine a sector yardstick m_yard(S) from fixed sector constants associated with the sector S; a mass-evaluation module configured to compute a fermion mass m_f according to: m_f=m_yard(S)*phi\hat{ }(r_f); and an output module configured to output the mass m_f, wherein the system generates the mass m_f without per-species fitted mass parameters.

16. The system of claim 15, wherein the generation torsion module is configured to assign: tau(0)=0, tau(1)=11, and tau(2)=17.

17. The system of claim 15, wherein the output module is configured to, responsive to a determination that the fermion identifier (i) is unsupported, (ii) is ambiguous, (iii) maps to an unsupported sector, (iv) maps to an unsupported generation, or (v) has an invalid request format, output a machine-readable status output in lieu of outputting the mass m_f.

18. The system of claim 15, wherein the system is configured to generate a precomputed machine-readable mass table comprising masses for a plurality of supported fermions, store the precomputed machine-readable mass table in a non-transitory storage medium, and output at least one mass value retrieved from the precomputed machine-readable mass table.

19. A non-transitory computer-readable medium storing instructions that, when executed by one or more processors, cause the one or more processors to: receive a fermion identifier; determine a sector S and a generation g associated with a fermion; assign a generation torsion value tau(g); assign a species rung r_f from the sector S and the generation torsion value tau(g); determine a sector yardstick m_yard(S) from fixed sector constants associated with the sector S; compute a mass m_f according to: m_f=m_yard(S)*phi\hat{ }(r_f); and output the mass m_f, wherein the mass m_f is generated without per-species fitted mass parameters.

20. The non-transitory computer-readable medium of claim 19, wherein the instructions further cause the one or more processors to receive either (i) a fermion identifier comprising a particle name, symbol, or canonical species token or (ii) a direct sector-and-generation input, and to generate at least one of: a charged-fermion mass table, a structured output record, or a ratio output according to m_f/m_g=phi\hat{ }(r_f−r_g) for fermions within a common sector.
